(19) United States
(12) Patent Application Publication
(10) Pub. No.: US 2004/0235304 A1
(43) Pub. Date: Nov. 25, 2004

(54) Plasma treatment apparatus

(75) Inventor: Hin Oh, Nirasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/876,735

(22) Filed: Jun. 28, 2004

Related U.S. Application Data
(63) Continuation of application No. PCT/JP02/01385, filed on Dec. 27, 2002.

(30) Foreign Application Priority Data
Dec. 27, 2001 (JP) 2001-398608

(51) Int. Cl. H01L 21/302; H01L 21/461

(52) U.S. Cl. 438/689

(57) ABSTRACT

A plasma processing apparatus and processing method using same ensures to identify changes in a particular control parameter and/or an apparatus state parameter. The plasma processing apparatus includes a detection unit to detect a plasma reflection parameter representing a plasma state by using a high frequency electric power, a setting unit to set a plurality of control parameters to control the plasma state, a storage unit to store a model equation that predicts at least the control parameters and a number of apparatus state parameters based on the plasma reflection parameter, and a prediction unit for applying to the model equation the plasma reflection parameter obtained when processing an object to be processed to predict at least control parameters and apparatus state parameters during processing.

This application is a Continuation Application of PCT International Application No. PCT/JP02/13855 filed on Dec. 27, 2002, which designated the United States.

### FIELD OF THE INVENTION

The present invention relates to a plasma processing apparatus and a method for monitoring same.

### BACKGROUND OF THE INVENTION

Various processing apparatuses are used in a semiconductor manufacturing processes. A processing apparatus such as plasma processing apparatus has been widely used in a film forming or an etching process to treat an object to be processed such as a semiconductor wafer and a glass substrate. Each processing apparatus has unique process characteristics for a different object to be processed type. Accordingly, the characteristics of each apparatus' process are monitored and predicted for optimum processing of a wafer.

For example, Japanese Patent Laid-open Publication No. 1994-132251 discloses an etching monitoring scheme for a plasma etching apparatus. Beforehand, this scheme correlates etching processing results (uniformity, dimensional accuracy, shape, under-film selectivity etc.) with plasma spectrum analysis results and/or with process condition changes (pressure, gas flow rate, bias voltage etc.); the relationships therebetween are stored as a database, which is used to monitor processing results indirectly, without directly examining a wafer. If monitored processing results do not satisfy the inspection standards, the information thereof is transmitted to the etching apparatus to modify processing conditions or to stop the process, and at the same time, an operator is notified of the situation.

In addition, Japanese Patent Laid-open Publication No. 1998-125660 discloses a process monitoring scheme for a plasma processing apparatus. In this case, before processing, a model equation, which correlates the electrical signal representing a plasma state with the plasma state in the processing chamber (processing characteristics), is derived using a test wafer. Thereafter, measured electrical signal values obtained while processing actual wafers are applied to the model equation to predict and diagnose the actual plasma state.

Furthermore, Japanese Patent Laid-open Publication No. 1999-87323 discloses a method and apparatus for monitoring processes of a semiconductor wafer processing system using multiple process parameters thereof. This method analyzes and statistically correlates the multiple process parameters in order to detect changes in the process or system characteristics. The multiple process parameters used include emission, environmental parameters (e.g., temperature and pressure of the reaction chamber), RF power parameters (e.g., reflection power and tuning voltage), and system parameters (e.g., specific system configuration and control voltage).

All of the aforementioned techniques indirectly inspect processing result qualities, predict a plasma state or evaluate changes in system characteristics, e.g., end point of etching, contamination in the processing chamber, by statistically correlating process condition changes with wafer processing results. With these techniques, one cannot directly monitor change with time in each control parameters, e.g., pressure in the processing chamber and process gas flow rate, that can be regulated and that directly affect wafer processing or in each apparatus state parameters, e.g., high frequency voltage, that are associated with the apparatus state. If any one of the parameters deviates from its normal range, one cannot identify the source; further, one cannot know the operating condition while processing. In addition, not only one cannot identify the source of an abnormality as either a control parameter or an apparatus state parameter, the issue still remains that investigating the source of such an abnormality would be time consuming.

### SUMMARY OF THE INVENTION

It is, therefore, an object of the present invention to solve the aforementioned problems, not only to provide the capability to monitor in real time changes in each control parameter and/or each apparatus state parameter, but also to provide a plasma processing apparatus, a monitoring scheme for a plasma processing apparatus and a plasma processing method, all of which are capable of identifying changes in a particular control parameter and/or an apparatus state parameter.

In accordance with one aspect of the invention, there is provided a plasma processing apparatus including: a detection unit to detect a plasma reflection parameter representing a plasma state while processing an object to be processed by using a high frequency electric power; a setting unit to set a plurality of control parameters to control the plasma state; a storage unit to store a model equation that predicts at least the control parameters and a number of apparatus state parameters based on the plasma reflection parameter; and a prediction unit for applying to the model equation the plasma reflection parameter obtained when processing an object to be processed to predict at least control parameters and apparatus state parameters during processing.

In accordance with another aspect of the invention, there is provided a method for monitoring a plasma processing apparatus, which includes a detection unit to detect a plasma reflection parameter representing a plasma state while processing an object to be processed by using a high frequency electric power; a setting unit to set a plurality of control parameters to control the plasma state; a storage unit to store a model equation that predicts at least the control parameters and a number of apparatus state parameters based on the plasma reflection parameter; and a prediction unit for applying to the model equation the plasma reflection parameter obtained when processing an object to be processed to predict at least control parameters and apparatus state parameters during processing, the method including the steps of: detecting the plasma reflection parameter representing the plasma state while processing the object to be processed by using the high frequency electric power; and predicting at least control parameters and apparatus state parameters during processing by applying to the model equation the plasma reflection parameter.

In accordance with still another aspect of the invention, there is provided a plasma processing method for processing an object to be processed by employing a plasma processing apparatus, the method including the steps of: detecting a plasma reflection parameter representing a plasma state while processing the object to be processed by using a high frequency electric power; and predicting at least control parameters and apparatus state parameters during processing by applying to a model equation the plasma reflection parameter.

### BRIEF DESCRIPTION OF THE DRAWINGS

FIG. 1 offers a schematic cross sectional view of a plasma processing apparatus in accordance with a preferred embodiment of the present invention;

FIG. 2 presents a block diagram of an example of the multivariate analysis unit of the apparatus offered in FIG. 1;

FIG. 3A provides 3-D coordinate space plotting of each element of a matrix X made up of explanatory variables (electrical data and optical data) used in multivariate analysis;

FIG. 3B provides 3-D coordinate space plotting of each element of a matrix Y made up of objective variables (control parameters and apparatus state parameters);

FIGS. 4A and 4B offer 3-D coordinate space plotting of a first PLS principal component of the explanatory variables in FIG. 3A and that of the objective variables in FIG. 3B, respectively;

FIG. 5 describes coordinate space plotting of scores of explanatory variables and objective variables obtained from the first PLS principal component in FIGS. 4A and 4B;

FIG. 6 illustrates dimensions of vectors in an algorithm of a PLS method;

FIG. 7 offers a comparison graph between prediction values and actual measurement values of a high frequency power by using a model equation;

FIG. 8 offers a comparison graph between prediction values and actual measurement values of a pressure in a processing chamber by using the model equation;

FIG. 9 offers a comparison graph between prediction values and actual measurement values of a gap between an upper electrode and a lower electrode by using the model equation;

FIG. 10 offers a comparison graph between prediction values and actual measurement values of an Ar flow rate by using the model equation;

FIG. 11 offers a comparison graph between prediction values and actual measurement values of a CO flow rate by using the model equation;

FIG. 12 offers a comparison graph between prediction values and actual measurement values of a C₄F₈ flow rate by using the model equation;

FIG. 13 offers a comparison graph between prediction values and actual measurement values of an O₂ flow rate by using the model equation;

FIG. 14 offers a comparison graph between prediction values and actual measurement values of a high frequency voltage by using the model equation;

FIG. 15 offers a comparison graph between prediction values and actual measurement values of an opening ratio of an APC by using the model equation;

FIG. 16 offers a comparison graph between prediction values and actual measurement values of a capacity of a matching unit's variable capacitor by using the model equation;

FIG. 17 offers a comparison graph between prediction values and actual measurement values of a capacity of the matching unit's another variable capacitor by using the model equation;

FIGS. 18A and 18B give a graph and a table on a prediction accuracy of the model equation;

FIG. 19 presents a a correlation graph between prediction values and actual measurement values of the high frequency power;

FIG. 20 presents a correlation graph between prediction values and actual measurement values of the pressure in the processing chamber;

FIG. 21 presents a correlation graph between prediction values and actual measurement values of the electrodes' gap distance;

FIG. 22 presents a correlation graph between prediction values and actual measurement values of an Ar gas flow rate;

FIG. 23 presents a correlation graph between prediction values and actual measurement values of an O₂ gas flow rate;

FIG. 24 presents a correlation graph between prediction values and actual measurement values of a CO gas flow rate;

FIG. 25 presents a correlation graph between prediction values and actual measurement values of a C₄F₈ gas flow rate;

FIG. 26 presents a correlation graph between prediction values and actual measurement values of the high frequency voltage;

FIG. 27 presents a correlation graph between prediction values and actual measurement values of the opening ratio of the APC;

FIG. 28 presents a correlation graph between prediction values and actual measurement values of the variable condenser; and

FIG. 29 presents a correlation graph between prediction values and actual measurement values of another variable condenser;

### DETAILED DESCRIPTION OF THE PREFERRED EMBODIMENT

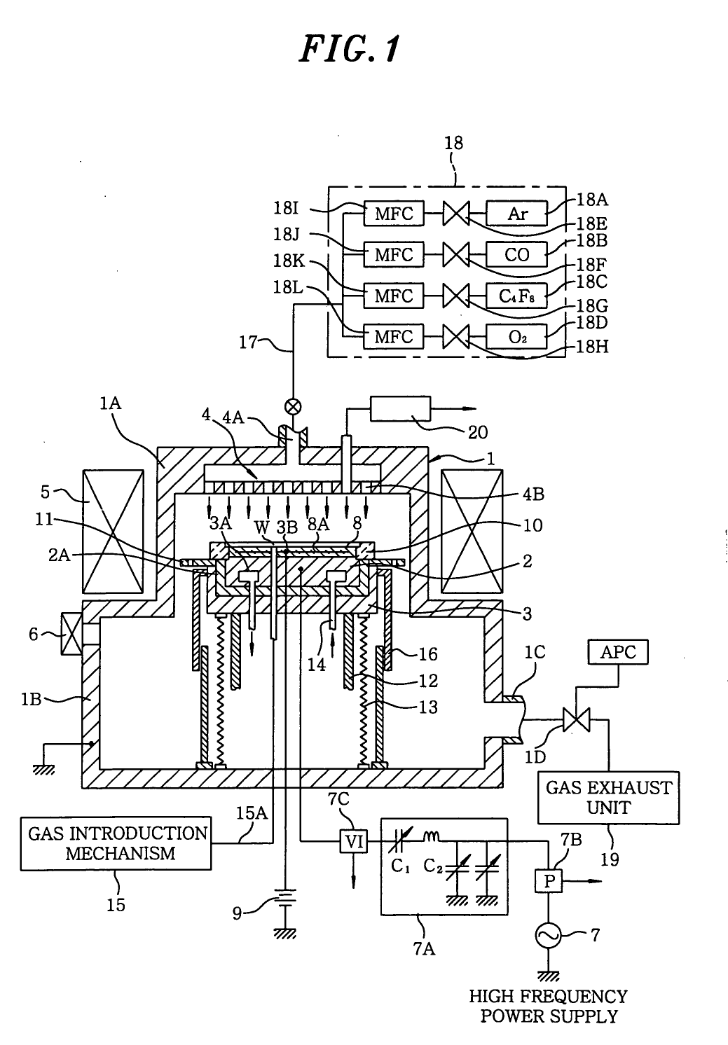

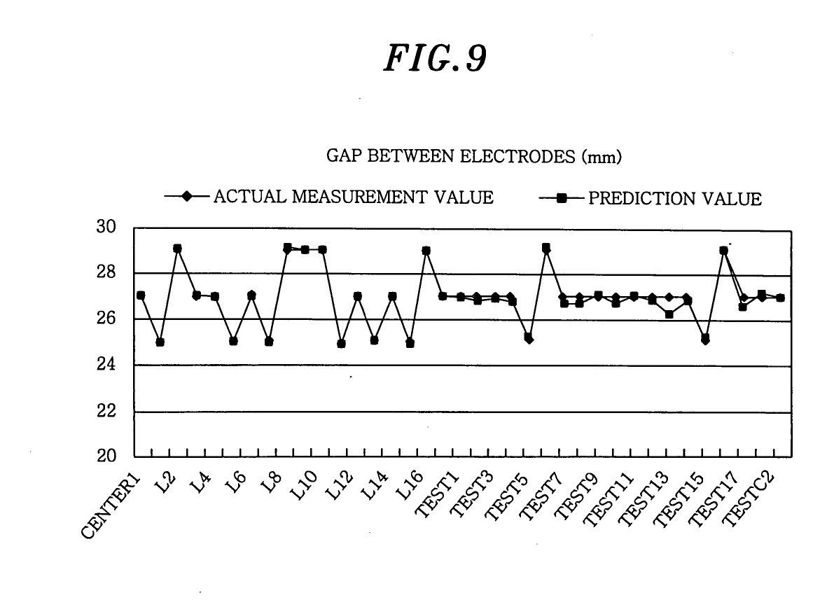

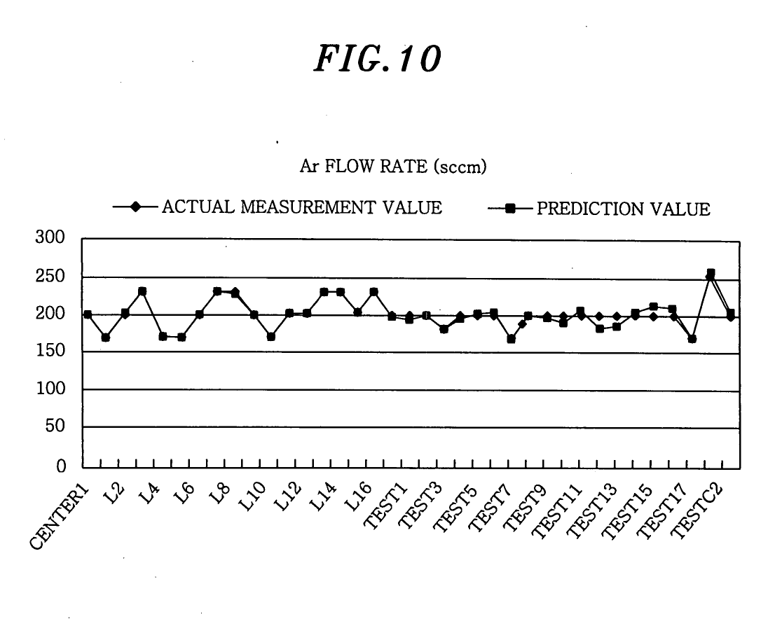

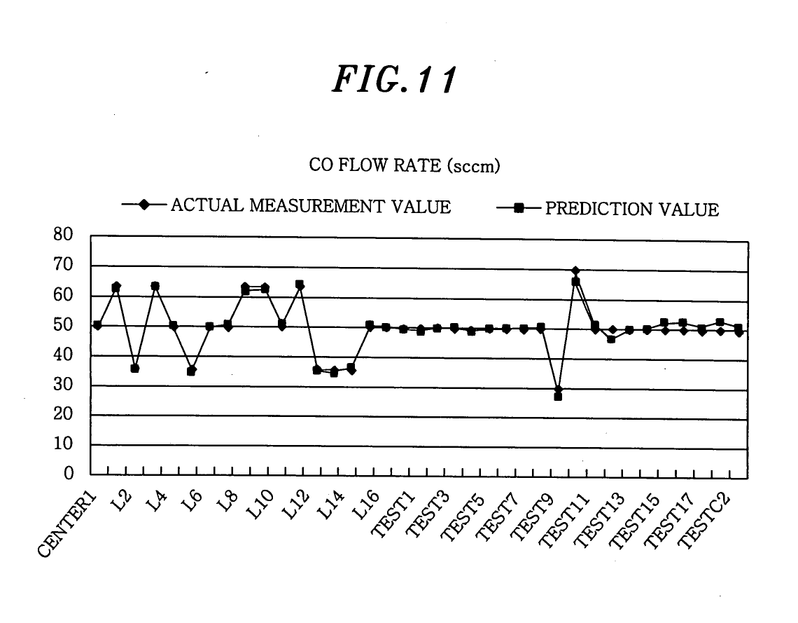

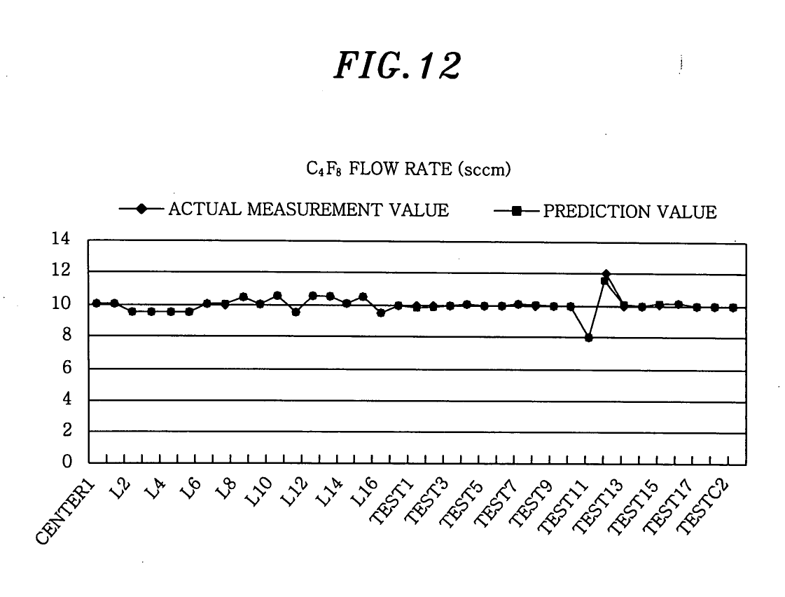

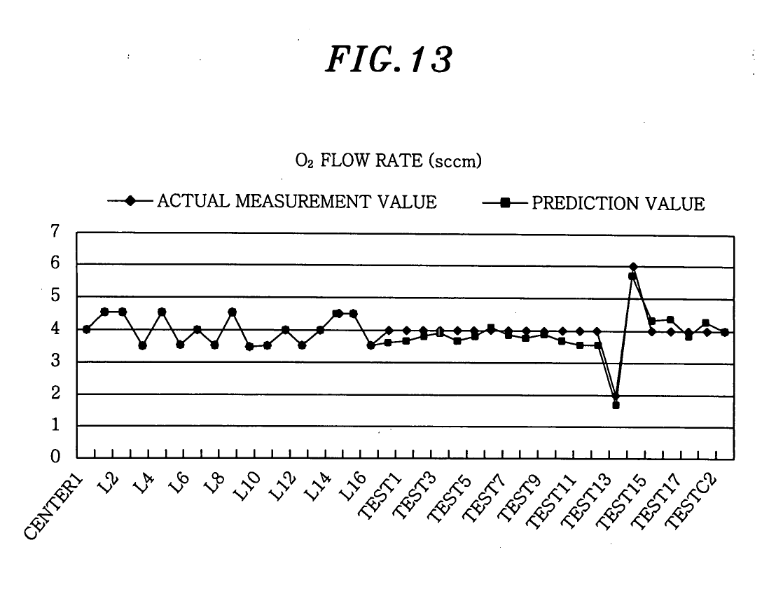

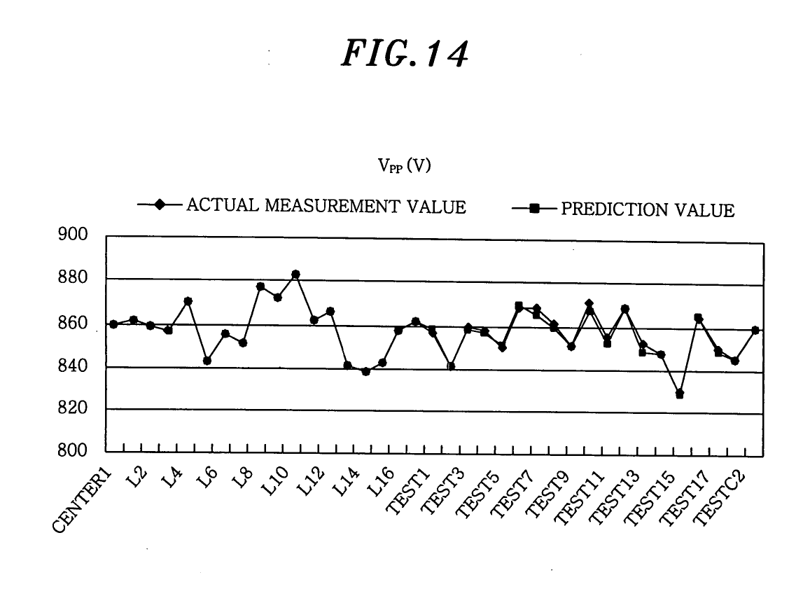

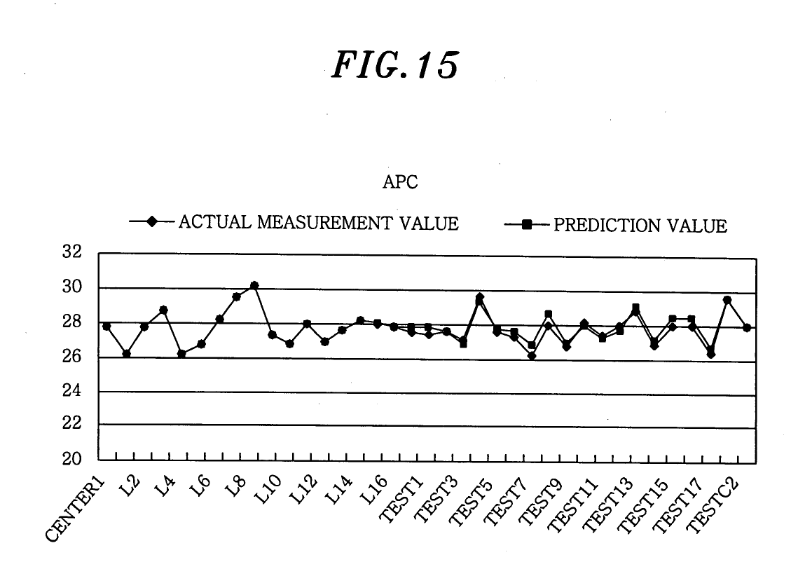

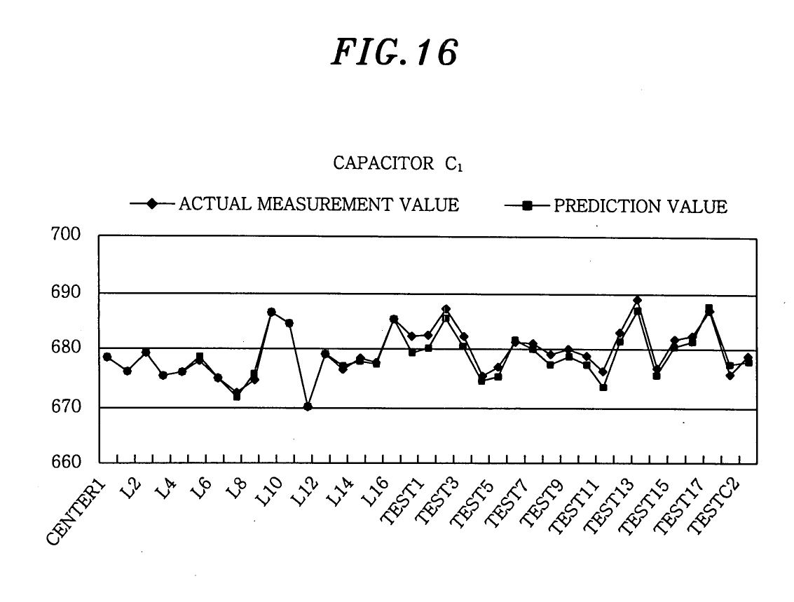

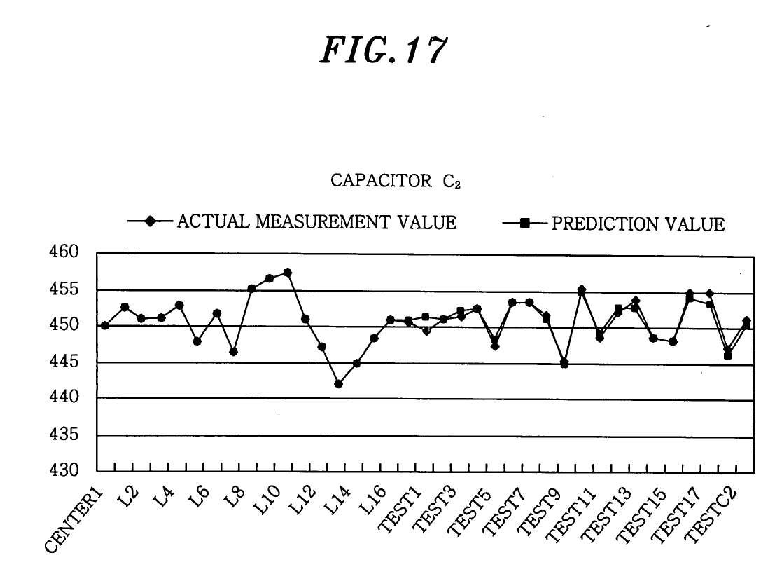

Hereinafter, the present invention is described based on a preferred embodiment with reference to FIGS. 1 to 18.

First, a plasma processing apparatus in accordance with the preferred embodiment is described. The plasma processing apparatus of the preferred embodiment includes a processing chamber 1 made of aluminum; a vertically movable supporting body 3 made of aluminum for supporting a lower electrode 2 installed in the processing chamber 1 through an insulating member 2A; and a shower head (hereinafter referred to as an “upper electrode” when necessary) 4 disposed above the supporting body 3 for supplying a processing gas as well as serving as an upper electrode, as illustrated in FIG. 1.

The processing chamber 1 has an upper room 1A with a small diameter in an upper portion thereof, and a lower room 1B with a large diameter in a lower portion thereof. The upper room 1A is surrounded by a dipole ring magnet 5. The dipole ring magnet 5 is constructed in such a way that a plurality of columnar anisotropic segment magnets are arranged in a casing formed of a ring-shape magnetic body. As a result, equal horizontal magnetic fields that point in one direction are produced in the upper room 1A. In an upper portion of the lower room 1B, a gate is disposed through which a wafer W is loaded and unloaded. A gate valve 6 is disposed thereon. The lower electrode 2 is connected to a high frequency power supply 7 through a matching unit 7A. A high frequency power P at 13.56 MHz is supplied to the lower electrode 2 from the high frequency power supply 7. Accordingly, vertical electric fields running between the lower electrode 2 and the upper electrode 4 in the upper room 1A are established. The high frequency power P is measured by using a power meter 7B disposed between the high frequency power supply 7 and the matching unit 7A. The high frequency power P is a controllable parameter. In this preferred embodiment, the high frequency power P, together with other controllable parameters such as a gas flow rate, a gap between the electrodes as explained later, are defined as control parameters.

In addition, an electrical measurement device 7C (such as a VI probe) is disposed on the lower electrode 2 side (output side of the high frequency voltage) of the matching unit 7A. By using the measurement device 7C, a high frequency voltage V and a high frequency current I of a plasma's fundamental and harmonic waves, which are generated in the upper room 1A based on the high frequency power P applied to the lower electrode 2, are detected as electrical data. The electrical, together with optical data as will be explained later are monitorable parameters that reflect a plasma state. Accordingly, in this preferred embodiment, the electrical data and optical data are defined as plasma reflection parameters.

Further, the matching unit 7A has two variable capacitors C1 and C2, a capacitor C and a coil L therein; the matching unit performs impedance matching via C1 and C2. Respective capacitances of C1 and C2 under a matching state and a high frequency voltage Vpp as measured by a measuring device (not shown) disposed in the matching unit 7A together with an opening ratio of an APC (Auto Pressure Controller), which will be described later, are parameters that indicate an apparatus state during operation. Accordingly, in this preferred embodiment, the respective capacitances of the variable capacitors C1 and C2, the high frequency voltage Vpp and the opening ratio of the APC are defined as apparatus state parameters.

An electrostatic chuck 8 is disposed on a top surface of the lower electrode 2. An electrode plate 8A of the electrostatic chuck 8 is connected to a DC power supply 9. Therefore, under a high vacuum state, a high voltage from the DC power supply 9 is applied to the electrode plate 8A so that the wafer W is electrostatically adsorbed by the electrostatic chuck 8. Disposed on a peripheral portion of the lower electrode 2 is a focus ring 10 whereby the plasma generated in the upper room 1A is directed to the wafer W. Further, a gas exhaust ring 11 is disposed between the bottom portion of the focus ring 10 and the top portion of the supporting body 3. The gas exhaust ring 11 has a plurality of holes that are equi-distanced from the ring's circumference along its entire periphery. Through these holes, gas in the upper room 1A is discharged to the lower room 1B.

The supporting body 3 is designed so that it is vertically movable in the upper room 1A and the lower room 1B through a ball screw mechanism 12 and a bellows 13. Accordingly, loading steps for the wafer W onto the lower electrode 2 are: the lower electrode 2 is lowered to the lower room 1B by the supporting body 3; the gate valve 6 is opened; and the wafer W is loaded onto the lower electrode 2 by a delivery mechanism (not shown). The gap between the lower electrode 2 and the upper electrode 4 is regarded as a control parameter that can be set to a predetermined value as described above. Further, disposed in the supporting body 3 is a coolant path 3A, which is connected to a coolant line 14. A coolant is circulated in the coolant path 3A through the coolant line 14, thereby maintaining the wafer W at a predetermined temperature. Moreover, a gas channel 3B is disposed in the supporting body 3, the insulating member 2A, the lower electrode 2, and the electrostatic chuck 8, respectively, thereby supplying a He gas at a predetermined pressure as a backside gas to a narrow slit between the electrostatic chuck 8 and the wafer W, through a gas line 15A from a gas introduction mechanism 15. The He gas enhances heat transfer between the electrostatic chuck 8 and the wafer W. In addition, the reference number 16 indicates a bellows cover.

A gas inlet 4A is disposed at a top surface of the shower head 4 and is connected to a processing gas supply system 18 through a line 17. The processing gas supply system 18 has an Ar gas source 18A, a CO gas source 18B, a C₄F₈ gas source 18C and an O₂ gas source 18D. These gas sources 18A, 18B, 18C and 18D supply gases thereof at predetermined flow rates to the shower head 4 through valves 18E, 18F, 18G and 18H and mass flow controllers 18I, 18J, 18K and 18L, respectively, so that a gas mixture with a predetermined composition is introduced into the shower head 4. Each gas flow rate is a controllable parameter that can be measured by the corresponding mass flow controllers 18I to 18L; accordingly, the flow rates are defined as control parameters as described earlier.

A plurality of holes 4B are uniformly disposed over an entire bottom surface of the shower head 4. Through these holes 4B, the gas mixture is supplied as a processing gas into the upper room 1A from the shower head 4. Further, a gas exhaust line 1C is connected to a gas exhaust port of the lower room 1B. A Gas in the processing chamber 1 is exhausted through a gas exhaust unit 19 having a vacuum pump connected to the gas exhaust line 1C and a predetermined gas pressure level is maintained in the chamber. An APC valve 1D is disposed in the gas exhaust line 1C and an opening ratio of the APC valve 1D is automatically adjusted according to the pressure level in the processing chamber 1. This opening ratio is an apparatus state parameter reflecting the state of an apparatus, which is not controllable.

Further, a spectrometer 20 (hereinafter referred to as an “optical measurement device”) is disposed above the shower head 4 for detecting plasma emissions in the processing chamber 1. Based on optical data of a specific wavelength obtained by the optical measurement device 20, a plasma state is monitored and the end point of a plasma process is detected. Accordingly, a plasma reflection parameter reflecting the plasma state includes this optical data and electrical data based on the plasma generated by the high frequency power P.

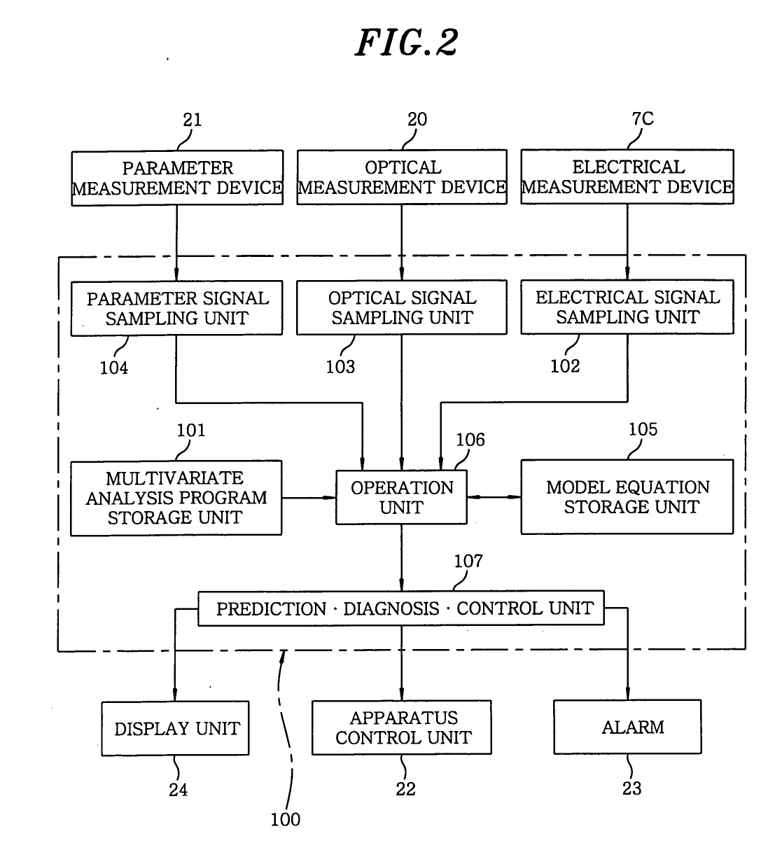

Furthermore, as illustrated in FIG. 2, the plasma processing apparatus includes a multivariate analysis unit 100. The multivariate analysis unit 100 has the following components: a multivariate analysis program storage unit 101 for storing a multivariate analysis program; an electrical signal sampling unit 102 for intermittently sampling signals from the electrical measurement device 7C; an optical signal sampling unit 103 for intermittently sampling signals from the optical measurement device 20; a parameter signal sampling unit 104 for intermittently sampling signals from a parameter measurement device 21; a model equation storage unit 105 for storing a model equation to predict a plurality of control parameters and/or apparatus state parameters based on a plurality of plasma reflection parameters (electrical data and optical data); an operation unit 106 for calculating the plurality of control parameters and/or apparatus state parameters with the model equation; and a prediction•diagnosis•control unit 107 for predicting, diagnosing and controlling the control parameters and/or apparatus state parameters based on operation results of the operation unit 106. In addition, the multivariate analysis unit 100 is also connected to an apparatus control unit 22 for controlling the plasma processing apparatus, an alarm 23 and a display unit 24. The apparatus control unit 22, for example, continues or interrupts the wafer W processing process based on signals from the prediction•diagnosis•control unit 107. The alarm 23 and the display unit 24 report any abnormalities of the control parameters and/or apparatus state parameters based on signals from the prediction•diagnosis•control unit 107 as described later. Further, the parameter measurement device 21 as shown in FIG. 2 represents the plurality of parameter measurement devices, such as a flow rate detector, in a single block.

This preferred embodiment employs a Partial Least Squares method (hereinafter referred to as a “PLS method”), which is a type of multivariate analysis. The PLS method is set up in the following manner: the plurality of plasma reflection parameters (electrical data and optical data) are set as explanatory variables; the plurality of control parameters and apparatus state parameters are set as objective variables; and a model equation to correlate these two variable types is derived. The matrix X's cells are composed of a number of explanatory variables; the matrix Y's cells are composed of a number of objective variables. Since both the electrical signals and optical signals are signals that reflect the plasma state, the respective data thereof are expressed as linear equations in the multivariate analysis. The operation unit 106 employs the PLS method to produce the model equation based on the explanatory variables and objective variables. As explained before, the model equation is then stored in the model equation storage unit 105.

When obtaining the model equation by using the PLS method as explained above, a plurality of explanatory and objective variables are measured in advance by an experimental run performed using a training set of wafers. Accordingly, a set of 18 wafers (TH-OX Si) is prepared, and TH-OX Si indicates wafers coated with a thermal oxide layer. In this case, such an experiment plan approach helps effective setting of each parameter data. In this preferred embodiment, for example, the control parameters that serve as the objective variables are assigned, within a predetermined range centering around a standard value, to each training wafer; thereafter, the training wafers are etched. Subsequently, the electrical data and optical data serving as the explanatory variables during the etching process are measured multiple times with respect to each training wafer. Averages of the electrical data and optical data are calculated by the operation unit 106, and they are used as the plasma reflection parameters. In this procedure, a maximum variation range of control parameters during the etching process is determined, and the control parameters are assigned within this range. In this preferred embodiment, the following are used as the control parameters: the high frequency power; the pressure in the processing chamber 1; a gap distance between the upper and lower electrodes 2 and 4; and the flow rate of each processing gas (Ar gas, CO gas, C₄F₈ gas, and O₂ gas). A standard value of each control parameter depends on an etching object type.

For instance, when etching is performed on each training wafer, the control parameters centering around standard values are assigned to each training wafer in the range of level 1 to level 2 shown in Table 1 below. While each training wafer is processed, the high frequency voltage V (from the fundamental wave to a quadruple wave) and the high frequency current I (from the fundamental wave to the quadruple wave) based on the plasma are measured as electrical data by the electrical measurement device 7C; and an emission spectrum intensity of a wavelength in the range of 200 to 950 nm is measured as optical data by the optical measurement device 20. The electrical data and optical data are used as the plasma reflection parameters. At the same time, each actual measurement value of control parameters shown in Table 1 and those of the apparatus state parameters, e.g., a capacitance of each variable capacitor C1 and C2, a harmonic wave voltage Vpp, the opening ratio of the APC, are measured by the respective parameter measurement device 21.

TABLE 1

| | | Pressure | | | | | |
|---|---|---|---|---|---|---|---|
| | Power W | mTorr | Gap mm | Ar sccm | CO sccm | C₄F₈ sccm | O₂ sccm |
| Level 1 | 1460 | 38 | 25 | 170 | 36 | 9.5 | 3.5 |
| Standard | 1500 | 40 | 27 | 200 | 50 | 10 | 4 |
| value | | | | | | | |
| Level 2 | 1540 | 42 | 29 | 230 | 64 | 10.5 | 4.5 |
| | 2.67% | 5.00% | 7.41% | 15.00% | 28.00% | 5.00% | 12.50% |

In processing the training wafers, each of the above control parameters is set to the standard value of the thermal oxide layer, and five dummy wafers are processed in accordance with the standard values, thereby stabilizing the plasma processing apparatus. Subsequently, eighteen training wafers are etched. In this procedure, each control parameter is varied (assigned) to each training wafer in the range of level 1 to level 2 as shown in Table 2 below. After obtaining the plurality of electrical data and optical data of each training wafer by the respective measurement devices, each average of the electrical data and optical data of each training wafer data are calculated; the actual measurement values of the plurality of control and apparatus state parameters are also averaged. These average values are used as the explanatory variables and objective variables, respectively. Further, in Table 2 below, reference numbers (L1 to L18) indicate the training wafer indices.

TABLE 2

| | Pressure | Ar | CO | C₄F₈ | O₂ | Gap | Power |
|---|---|---|---|---|---|---|---|
| No. | [mTorr] | [sccm] | [sccm] | [sccm] | [sccm] | [mm] | [W] |
| L1 | 42 | 170 | 64 | 10 | 4.5 | 25 | 1500 |
| L2 | 38 | 200 | 36 | 9.5 | 4.5 | 29 | 1500 |
| L3 | 40 | 230 | 64 | 9.5 | 3.5 | 27 | 1500 |
| L4 | 42 | 170 | 50 | 9.5 | 4.5 | 27 | 1540 |
| L5 | 38 | 170 | 36 | 9.5 | 3.5 | 25 | 1460 |
| L6 | 38 | 200 | 50 | 10 | 4 | 27 | 1500 |
| L7 | 38 | 230 | 50 | 10 | 3.5 | 25 | 1540 |
| L8 | 38 | 230 | 64 | 10.5 | 4.5 | 29 | 1540 |
| L9 | 42 | 200 | 64 | 10 | 3.5 | 29 | 1460 |
| L10 | 40 | 170 | 50 | 10.5 | 3.5 | 29 | 1500 |
| L11 | 40 | 200 | 64 | 9.5 | 4 | 25 | 1540 |
| L12 | 42 | 200 | 36 | 10.5 | 3.5 | 27 | 1540 |
| L13 | 42 | 230 | 36 | 10.5 | 4 | 25 | 1500 |
| L14 | 40 | 230 | 36 | 10 | 4.5 | 27 | 1460 |
| L15 | 40 | 200 | 50 | 10.5 | 4.5 | 25 | 1460 |
| L16 | 42 | 230 | 50 | 9.5 | 3.5 | 29 | 1460 |
| L17 | 40 | 170 | 36 | 10 | 3.5 | 29 | 1540 |
| L18 | 38 | 170 | 64 | 10.5 | 3.5 | 27 | 1460 |

The following explains a method for deriving the model equation with the explanatory variables and objective variables in accordance with the PLS method. A detailed explanation of the PLS method is disclosed, for example, in JOURNAL OF CHEMOMETRICSICS, VOL. 2 (PP. 211-228) (1998). In the PLS method, a relational equation (a regression equation) Eq \mathring{1} shown below is set up such that the electrical and optical data of each training wafer are the explanatory variables, and the plurality of control and apparatus state parameters are the objective variables. In the following regression equation Eq \mathring{1}, X represents a matrix of training wafers' explanatory variables, and Y a matrix of training wafers' objective variables. Further, B is a regression matrix, and E is a residual matrix.

Y=BX+E Eq. \mathring{1}

In accordance with the PLS method, even though a plurality of explanatory and objective variables are included in the matrices X and Y, respectively, the PLS method can provide a relational equation between X and Y so long as a small number of actual measurement values of the variables are available. Moreover, the PLS method is characterized by a high stability and reliability even if the relational expression is derived from only a small number of actual measurement values.

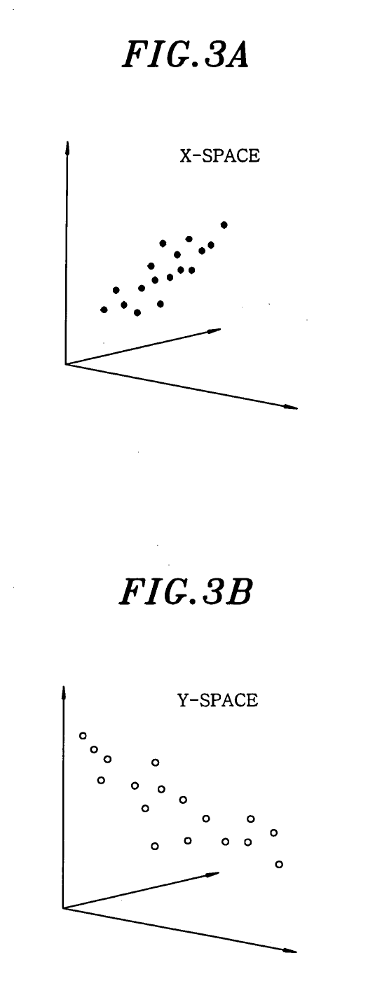

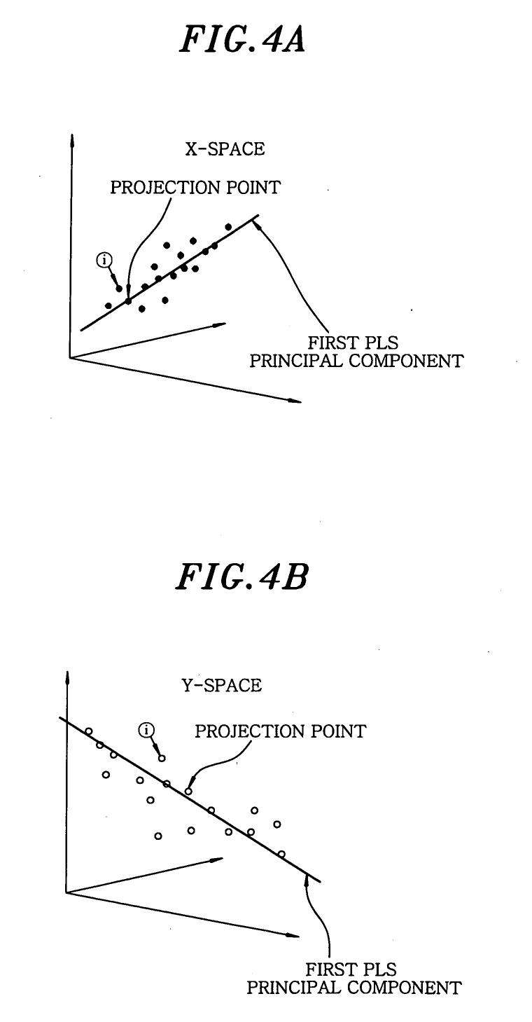

In using the PLS method, the existence as to any correlation between the explanatory variables and the corresponding objective variables of each training wafer is examined. In this procedure, for example, a value of each explanatory variable is plotted in a X-space where the coordinate axes are constructed by the respective explanatory variables in the matrix X regarding each training wafer as shown in FIG. 3A. Similarly, a value of each objective variable is plotted in a Y-space where the coordinate axes are constructed by the respective objective variables in the matrix Y regarding each training wafer as shown in FIG. 3B. Then, the PLS principal component analysis is performed with respect to a group made up of plots in the X-space and that in the Y-space, thereby obtaining a straight line (new coordinate axis) as a first PLS principal component analysis of the explanatory variables (FIG. 4A). A straight line (new coordinate axis) shown in FIG. 4B is obtained likewise as a first PLS principal component of the objective variables.

From the analysis results of FIGS. 4A and 4B, a correlation between each explanatory variable and each objective variable is obtained. In FIGS. 4A and 4B, i represents an i-th training wafer. In addition, a plot of each explanatory variable and that of each objective variable are projected onto the lines of each variable's first PLS principal components, thereby obtaining scores corresponding to each explanatory and objective variable.

Subsequently, a t₁-axis and a u₁-axis representing the scores of the explanatory variables and objective variables, respectively, are set up, and then the scores of the explanatory variables and those of the objective variables that correspond to each other are plotted thereon (FIG. 5). FIG. 5 shows that the scores of the explanatory variables and those of the objective scores are directly related to each other. That is, it is learned that the scores of the objective variables regress to those of the explanatory variables. If a regression line is obtained by using a least squares method, its gradient would be 1 (Uᵢ₁=tᵢ₁+hᵢ). In addition, a subscript i of u, t and h indicates an i-th training wafer whereas 1 of u and t indicates a score of the first PLS principal component.

The matrix X and Y are expressed as the following Eqs \mathring{2} and \mathring{3}, respectively, by using a loading matrix and a score matrix. Hereinafter, an index T represents a transpose matrix. T and U represent score matrices; P and C, loading matrices; and F and G, the residual matrices.

X=TP^{T}+F Eq. \mathring{2}

T=UC^{T}+G Eq. \mathring{3}

As described above, a correlation U=T+H exists between the score T of the matrix X and the score U of the matrix Y. Therefore, the equation Eq \mathring{3} can be expressed as the following Eq \mathring{4} by using the score T of the matrix X. G′ represents the residual matrix.

Y=TC^{T}+G′ Eq. \mathring{4}

In this preferred embodiment, the program for the PLS method is stored in the multivariate analysis program storage unit 101, so that the explanatory variables and objective variables are processed by the operation unit 106 according to the corresponding program sequence to obtain equation Eq \mathring{1}. The process results are stored in the model equation storage unit 105. After obtaining the equation Eq \mathring{1}, the plurality of electrical data and optical data serving as the plasma reflection parameters are applied to the matrix X as the explanatory variables in order to predict the plurality of control parameters and apparatus state parameters serving as the objective parameters. Further, the reliability of these prediction values becomes high.

In the PLS method, with respect to a matrix X^{T}Y constituted by adding the objective variables to the explanatory variables, an i-th PLS principal component corresponding to an i-th eigenvalue is represented by tᵢ. In addition, the matrix X is expressed by equation Eq \mathring{5} below by using both a score tᵢ and a loading pᵢ of the i-th PLS principal component, and similarly, the matrix Y is expressed as the equation Eq \mathring{6} below by using both the score tᵢ and a loading cᵢ of the i-th PLS principal component. In the following equations, Xᵢ₊₁ and Yᵢ₊₁ are the residual matrices of X and Y, respectively, and X^{T} is a transpose matrix of X. Hereinafter, an index T represents a transpose matrix.

X=t₁p₁+t₂p₂+t₃p₃+ . . . +tᵢpᵢ+Xᵢ₊₁+ Eq. \mathring{5}

Y=t₁C₁+t₂c₂+t₃c₃+ . . . +tᵢcᵢ+Yᵢ₊₁+ Eq. \mathring{6}

Accordingly, the PLS method calculates a plurality of eigenvalues and their eigenvectors from a small number of calculations when the equations Eqs \mathring{5} and \mathring{6} are correlated to each other. The PLS method is performed according to the following sequence.

That is, in a first stage, centering and scaling operations for the matrices X and Y are performed. Then, i is set to 1 so that X₁=X and Y₁=Y. Thereafter, the first column of the matrix Y₁ is set to u₁ where the centering represents an operation of subtracting an average of each row from the row's each element, and the scaling represents an operation of dividing each element of the row by the row's standard deviation.

In a second stage, after wᵢ=Xᵢ^{T}uᵢ/(uᵢ^{T}uᵢ) is calculated, a determinant of wᵢ is normalized and then tᵢ=Xᵢwᵢ is obtained. Further, the same process is executed for the matrix Y, i.e., after cᵢ=Yᵢ^{T}tᵢ/(t₁^{T}t₁) is calculated, a determinant of cᵢ is normalized, and then uᵢ=Yᵢcᵢ/(cᵢ^{T}cᵢ) is obtained.

In a third stage, a X loading Pᵢ=Xᵢ^{T}tᵢ/(tᵢ^{T}tᵢ) and a Y loading qᵢ=Yᵢ^{T}uᵢ/(uᵢ^{T}uᵢ) are obtained. Next, bᵢ=uᵢ^{T}tᵢ/(tᵢ^{T}tᵢ) is obtained by allowing u to regress to t. Subsequently, residual matrices Xᵢ=Xᵢ−tᵢpᵢ^{T} and Yᵢ=Yᵢ−bᵢtᵢcᵢ^{T} are obtainedi

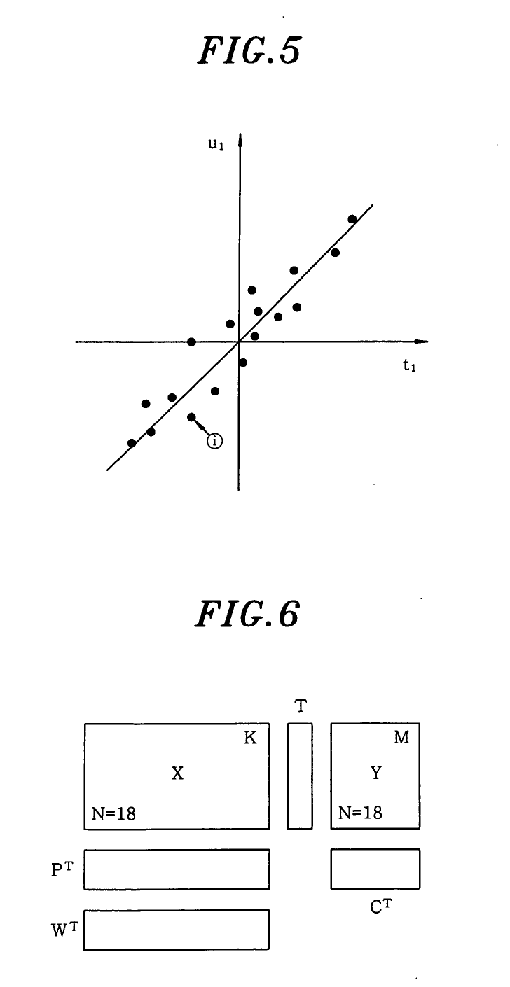

Further, after i is increased to be i+1, the processes of the second and third stages are repeated. These procedures are iterated by the PLS method's program until a predetermined stop condition is satisfied or the residual matrix Xᵢ₊₁ converges to zero, thereby obtaining a maximum eigenvalue and eigenvector of the residual matrix. The PLS method is characterized in that the residual matrix Xᵢ₊₁ rapidly converges to the stop condition or “0” by only repeating the above stages approximately ten times. Typically, the residual matrix converges to the stop condition or zero when the stages are iterated about four or five times. Through the use of the maximum eigenvalue and the eigenvector thereof from the process above, a first PLS principal component of the matrix X^{T}Y is obtained so that a maximum correlation between the matrices X and Y can be found. In the aforementioned algorithm, its vector dimensions shown in FIG. 6. In the figure, N, K and M are the number of the training wafers, the explanatory variables and the objective variables, respectively.

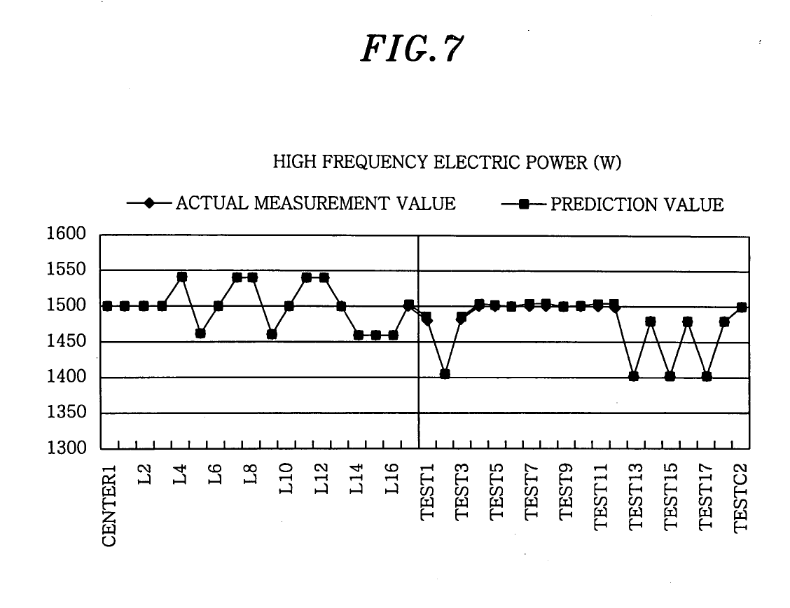

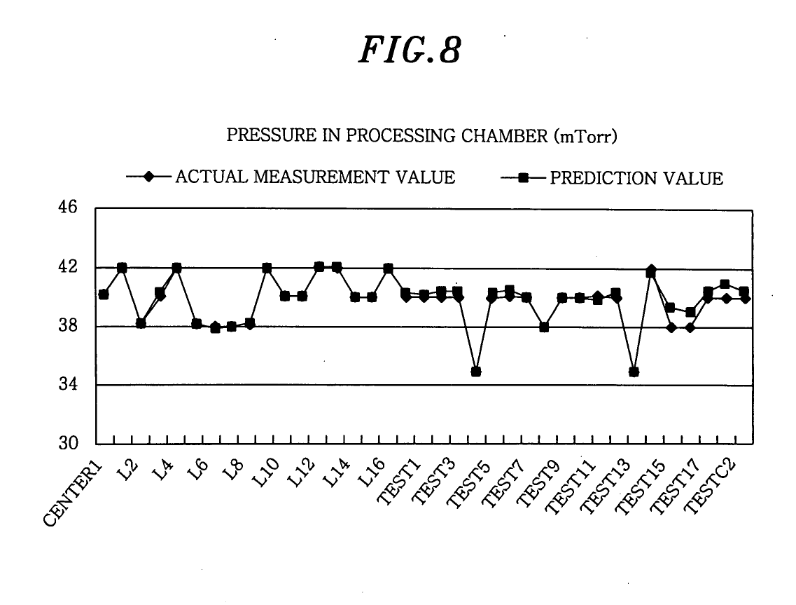

After obtaining a regression matrix B by using the PLS method, the explanatory variables of each training wafer, namely, the plurality of electrical and optical data, are stored in the model equation storage unit 105 and then applied to the equation Eq \mathring{1} inputted in the operation unit 10. Thereafter, prediction values of the objective variables, namely, the plurality of control parameters and the plurality of apparatus-state parameters while processing each training wafer are calculated. The prediction values represent expected values of the control parameters and apparatus-state parameters while processing the wafer W. The prediction values are plotted in the left half portions (portions indicated by L on the horizontal axis) in FIGS. 7 to 17. Observation values (actual measurement values) as well as the prediction values are shown in these charts. The actual measurement values are average parameters of the training wafers as measured by the respective measurement devices (e.g., the power meter 7B) for the control parameters and apparatus state parameters. As shown in the charts, regarding the control parameters used to obtain the model equation, the prediction and actual measurement values closely overlap. This is because the model equation is derived by using the plasma reflection parameters corresponding to the control parameters. More precisely, the prediction values represent set values (expected values) of the control parameters.

Hereinafter, prediction of the control parameters and apparatus state parameters by using test wafers (TH-OX Si) is explained. In this procedure, twenty test wafers are etched, and the control and apparatus state parameters are predicted by using the electrical data and optical data measured during a predetermined period.

First, the plasma processing apparatus is run after setting the plurality of control parameters to the standard process conditions as shown in Table 3, and five bare silicon wafers serving as dummy wafers are loaded into the processing chamber 1 to stabilize the plasma processing apparatus.

TABLE 3

| | Power | Pressure | Gap | Ar | CO | C₄F₈ | O₂ |
|---|---|---|---|---|---|---|---|
| No. | (W) | (mTorr) | (mm) | (sccm) | (sccm) | (sccm) | (sccm) |
| Bare Si | 1500 | 40 | 27 | 200 | 50 | 10 | 4 |
| 1 | | | | | | | |
| Bare Si | 1500 | 40 | 27 | 200 | 50 | 10 | 4 |
| 2 | | | | | | | |
| Bare Si | 1500 | 40 | 27 | 200 | 50 | 10 | 4 |
| 3 | | | | | | | |
| Bare Si | 1500 | 40 | 27 | 200 | 50 | 10 | 4 |
| 4 | | | | | | | |
| Bare Si | 1500 | 40 | 27 | 200 | 50 | 10 | 4 |
| 5 | | | | | | | |
| Bare Si | 1500 | 40 | 27 | 200 | 50 | 10 | 4 |
| 6 | | | | | | | |
| Bare Si | 1480 | 40 | 27 | 200 | 50 | 10 | 4 |
| 7 | | | | | | | |
| Bare Si | 1400 | 40 | 27 | 200 | 50 | 10 | 4 |
| 8 | | | | | | | |
| Bare Si | 1480 | 40 | 27 | 180 | 50 | 10 | 4 |
| 9 | | | | | | | |
| Bare Si | 1500 | 35 | 27 | 200 | 50 | 10 | 4 |
| 10 | | | | | | | |
| Bare Si | 1500 | 40 | 25 | 200 | 50 | 10 | 4 |
| 11 | | | | | | | |
| Bare Si | 1500 | 40 | 29 | 200 | 50 | 10 | 4 |
| 12 | | | | | | | |
| Bare Si | 1500 | 40 | 27 | 170 | 50 | 10 | 4 |
| 13 | | | | | | | |
| Bare Si | 1500 | 38 | 27 | 200 | 50 | 10 | 4 |
| 14 | | | | | | | |
| Bare Si | 1500 | 40 | 27 | 200 | 30 | 10 | 4 |
| 15 | | | | | | | |
| Bare Si | 1500 | 40 | 27 | 200 | 70 | 10 | 4 |
| 16 | | | | | | | |
| Bare Si | 1500 | 40 | 27 | 200 | 50 | 8 | 4 |
| 17 | | | | | | | |
| Bare Si | 1500 | 40 | 27 | 200 | 50 | 12 | 4 |
| 18 | | | | | | | |
| Bare Si | 1400 | 35 | 27 | 200 | 50 | 10 | 2 |
| 19 | | | | | | | |
| Bare Si | 1480 | 42 | 27 | 200 | 50 | 10 | 6 |
| 20 | | | | | | | |
| Bare Si | 1400 | 38 | 25 | 200 | 50 | 10 | 4 |
| 21 | | | | | | | |
| Bare Si | 1480 | 38 | 29 | 200 | 50 | 10 | 4 |
| 22 | | | | | | | |
| Bare Si | 1400 | 40 | 27 | 170 | 50 | 10 | 4 |
| 23 | | | | | | | |
| Bare Si | 1480 | 40 | 27 | 250 | 50 | 10 | 4 |
| 24 | | | | | | | |
| Bare Si | 1500 | 40 | 27 | 200 | 50 | 10 | 4 |
| 25 | | | | | | | |

In particular, after setting the gap between the upper electrode 2 and the lower electrodes 4 in the processing chamber 1 to 27 mm, operation of the plasma processing apparatus is started. The supporting body 3 is lowered to the lower room 1B of the processing chamber 1 by the ball screw mechanism 12 and, at the same time, the gate valve 6 is opened. Subsequently, the dummy wafer is brought into the processing chamber 1 through the loading/unloading opening and then is mounted on the lower electrode 2. After the wafer W is placed, the gate valve 6 is closed and, at the same time, the gas exhaust unit 19 is operated to maintain a predetermined vacuum level in the processing chamber 1. The opening ratio of the APC valve 1D is automatically controlled by the exhaust. At this time, the He gas is supplied as the back gas from the gas introduction mechanism 15; thus heat transfer between the wafer W and the lower electrode 2, more precisely between the electrostatic chuck 8 and the wafer W, is increased such that the cooling efficiency of the wafer W is enhanced.

In the meantime, the Ar gas, the CO gas, the C₄F₈ gas and the O₂ gas are supplied by the processing gas supply system 18 at flow rates of 200 sccm, 50 sccm, 10 sccm and 4 sccm, respectively. At this time, the pressure of the processing gas in the processing chamber 1 is set to 40 mTorr and the opening ratio of the APC valve 1D is automatically controlled according to the flow rate and discharge rate of the processing gas. Under this state, by applying a high frequency power of 1500 W from the high frequency power supply 7, a magnetron discharge occurs with the operation of the dipole ring magnet 5, thereby generating a plasma of the processing gas. Since the bare silicon wafer is first loaded, actual etching process is not performed at that time. After performing a processing action on the bare silicon wafer for a predetermined time period (e.g., 1 minute), the wafer W is carried out of the processing chamber 1 in the reverse order of the loading sequence. Up to the 5th dummy wafer, loading, processing and unloading are performed under the same conditions.

After stabilizing the plasma processing apparatus by processing the dummy wafers, test wafers are processed. An etching is performed on a first test wafer (a 6th wafer) with the control parameters set at the standard values. During this etching process, the electrical data and optical data are measured multiple times via the electrical measurement device 7C and the optical measurement device 20, respectively. The measured values are stored in a storage unit not shown. In addition, based on the measured values, the operation unit 106 calculates each average of the measured values. When processing a second test wafer, the high frequency power is lowered from 1500 W to 1480 W while the other control parameters are maintained at the aforementioned standard values; etching is performed thereafter. During the second etching process, the electrical data and optical data are measured and each average thereof is calculated in the same manner as for the first test wafer. When processing wafers after an 8-th wafer, each test wafer is etched with the control parameters set (varied) as shown in Table 3 above. In performing the etching process on each test wafer, the electrical and optical data are measured and each average thereof is computed.

While processing each test wafer, the operation unit 106 of the multivariate analysis unit 100 calculates the averages of the electrical data and optical data, which are then applied to the model equation from the model equation storage unit 105; thereafter, the prediction values of the plurality of control parameters and apparatus state parameters of each test wafer are obtained. The prediction •diagnosis•control unit 107 displays the calculated prediction values from the operation unit 106 on the display unit 24, along with the actual measurement values. The prediction values and actual measurement values of the plurality of control parameters and the plurality of apparatus state parameters of each test wafer upon conclusion of processing all test wafers are plotted in the right half portions (portions indicated by Test on horizontal axis) in FIGS. 7 to 17. As clearly shown by the charts, if the control parameter is changed (assigned) to a large or small value, the control parameters and the apparatus state parameters can be predicted by varying the prediction value in the same direction according to the control parameter.

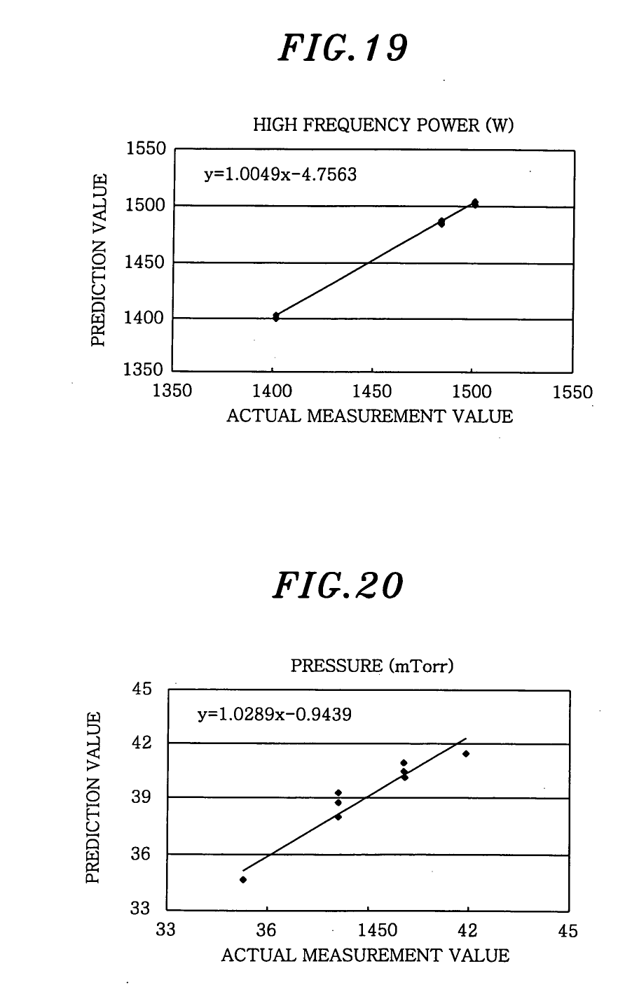

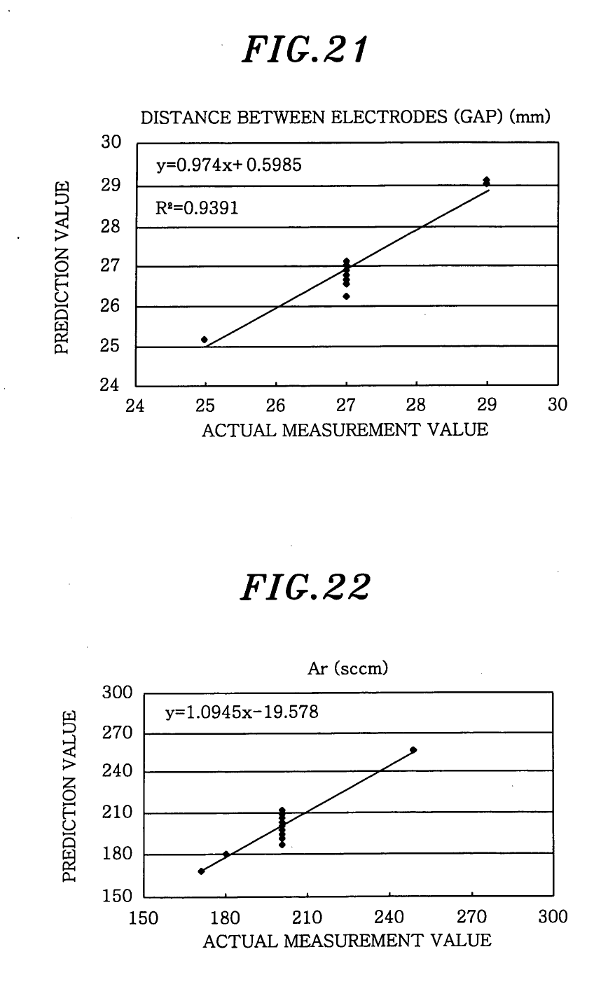

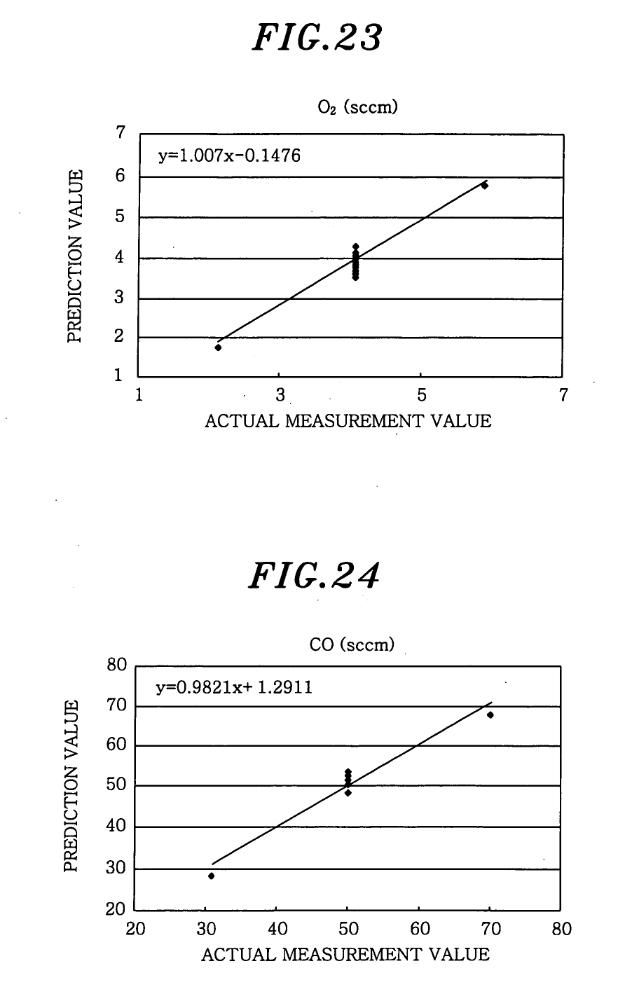

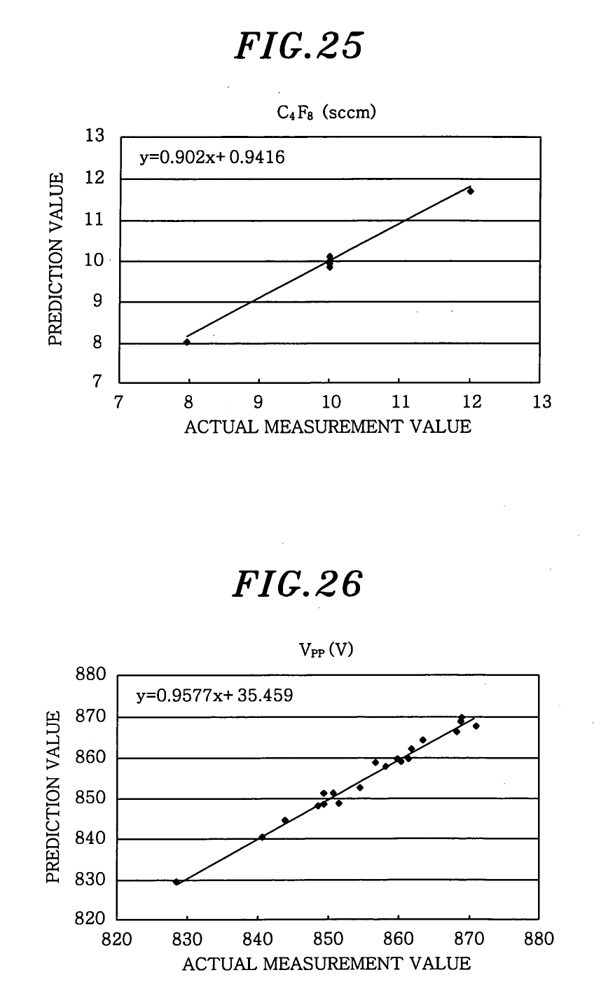

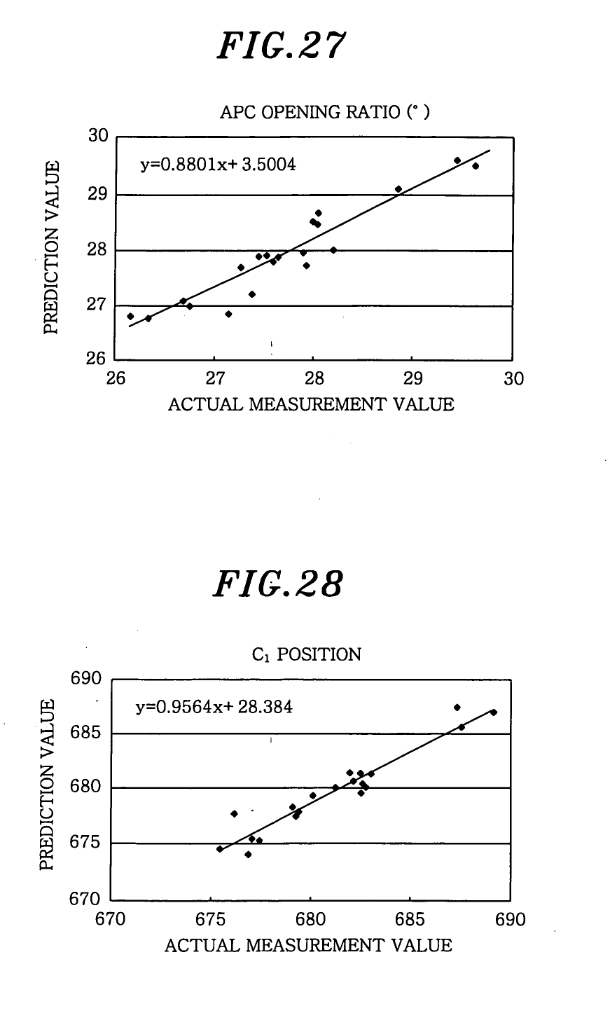

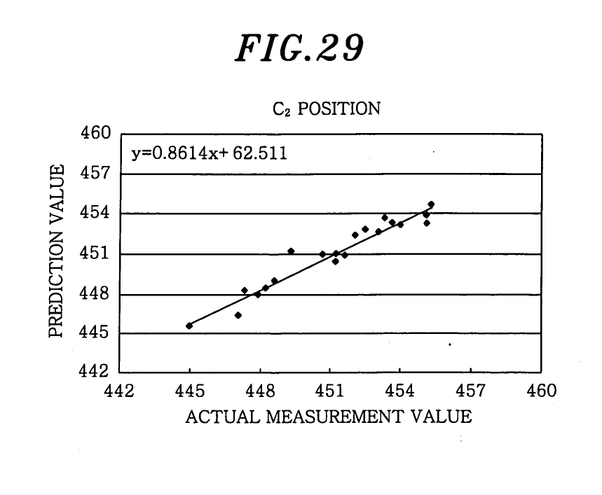

Correlations between the actual measurement values and the prediction values of the control parameters or the apparatus state parameters are depicted in FIGS. 19 to 29. As can be seen from the charts, a linear relationship with a gradient of 1 exists between the actual measurement values and prediction values; thus, the predictions are highly accurate. The equations shown in the charts approximate the linear expression equations, wherein the actual measurement values are represented by X and the prediction values by Y. Furthermore, the prediction•diagnosis•control unit 107 of the multivariate analysis unit 100 is able to detect discrepancies between the actual measurement values and prediction values (expected values) by comparing the two. When tolerance values of the discrepancies are predetermined, the prediction•diagnosis•control unit 107 can identify the origin of an abnormality among the plurality of the control parameters and apparatus state parameters; existence of an abnormality is notified by the alarm 23. If necessary, the plasma processing apparatus may be stopped by the apparatus control unit 22. Accordingly, since the plasma processing apparatus can always be operated in a normal state, a yield and productivity can be improved without generating errors in the process.

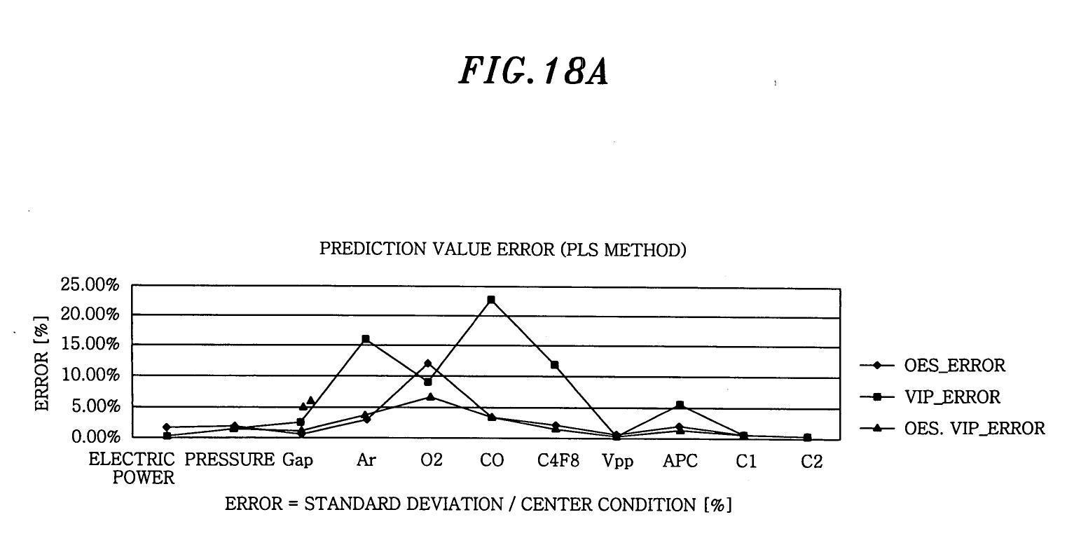

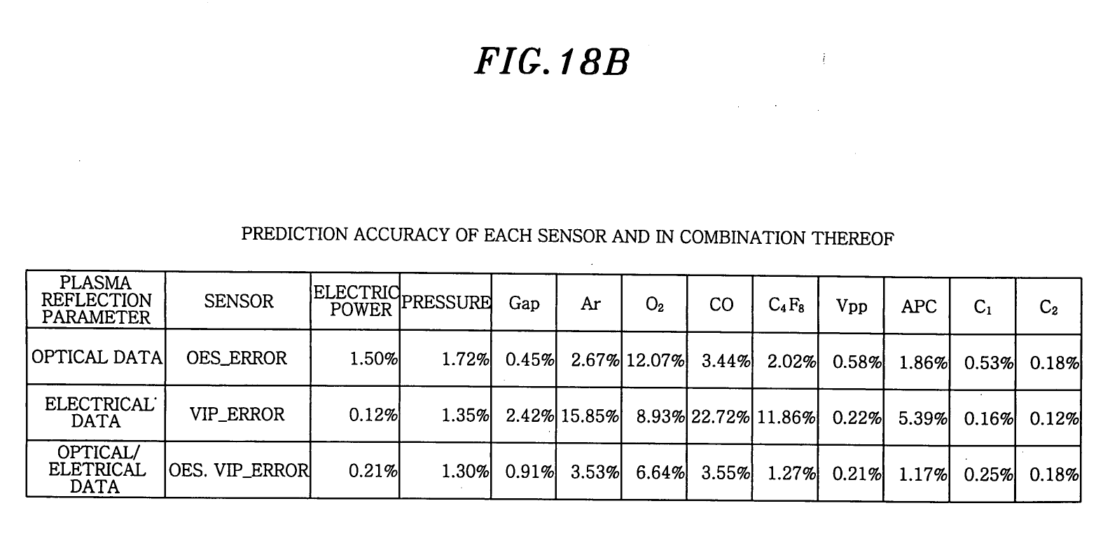

In the preferred embodiment described above, the control parameters and apparatus state parameters are predicted by using both the electrical data and optical data; however, it is also possible to predict the control parameters and apparatus state parameters by using only one of them. The prediction results (prediction accuracy) of the control parameters and apparatus state parameters taken under the same conditions as in the above embodiment, but only using either the electrical data or optical data, are shown in FIGS. 18A and 18B and compared with the results of the preferred embodiment. The prediction accuracy refers to a standard deviation value of the prediction value divided by the prediction value obtained under the standard condition in percentage. As shown in FIGS. 18A and 18B, when predicting the control parameters and apparatus state parameters only using the electrical data, the prediction accuracy of the control parameters and apparatus-state parameters related to the high frequency power such as Vpp, C1, and C2, are high. When the optical data is used only, the prediction values of the control parameters and apparatus state parameters related to the processing conditions other than the high frequency power such as the gap between the electrodes, the flow rate of each gas and the opening ratio of the APC, are high. Further, as can be seen from FIGS. 18A and 18B, while the prediction accuracies of the control parameters and apparatus state parameters are not greater than 6.64% and 1.17%, respectively when both the electrical data and optical data are used, the accuracies thereof are not greater than 22.72% and 5.39% when only the electrical data are used and 12.07% and 1.86% when only the optical data are used. Therefore, the prediction accuracies are much higher when both the electrical data and optical data are used.

As explained hitherto, in accordance with this preferred embodiment, when monitoring the plasma processing apparatus using the model equation for predicting the plurality of control parameters and/or the plurality of apparatus state parameters based on the plurality of plasma reflection parameters obtained while processing the wafer with the high frequency power, since each control parameter and/or each apparatus state parameter during the process are obtained by applying the plasma reflection parameters while processing a wafer to the model equation, specific change in each control parameter and/or apparatus state parameter can be monitored in real time while which of control or apparatus state parameter is changed can be identified.

Further, in accordance with the preferred embodiment of the present invention, since the prediction value of any one of the control parameters and/or apparatus-state parameters during the process is compared with its corresponding observation value (the actual measurement value), the degree of discrepancy between the actual measurement value and its expected value (prediction value) can be measured. Furthermore, since the abnormality of the parameter, which causes a change in the plasma state, is notified based on the above comparison results, not only can any abnormality of the apparatus state be discovered immediately, its cause can also be investigated. Therefore, the operation state of the plasma processing apparatus can be monitored in real time, thereby improving the yield and productivity without generating errors. Moreover, since the model equation is obtained by using the multivariate analysis, especially the PLS method, even with only a small number of electrical data and optical data the prediction, a model equation with high prediction accuracy can be derived. Further, in the PLS method, since the model equation is set up by applying the objective variables, highly accurate objective variables, namely, the control parameters and apparatus state parameters, can be predicted.

Further, in the above embodiment, in order to obtain the model equation, the high frequency power, the flow rate of the processing gas, the gap between the electrodes and the pressure in the processing chamber are used as the control parameters of the objective variables. However, the control parameters as the objective variables are not limited as such and other parameters can also be used provided they are controllable. Further, though the apparatus state parameters used are the capacitances of the variable capacitors, the high frequency voltage and the opening ratio of the APC, the parameters are not limited to them and other parameters can also be used instead provided they are measurable and indicate the apparatus state. Likewise, the electrical data and optical data based on the plasma are used as the plasma reflection parameters reflecting the plasma state, but other parameters can also be used provided they reflect the plasma state. Further, the electrical data are not limited to the high frequency voltage and current of the fundamental and harmonic waves (to the quadruple wave) as used in this embodiment. In the preferred embodiment of the present invention, the averages of the respective data of each wafer's plasma reflection parameters are obtained, and the control parameters and apparatus state parameters of each wafer are predicted by using the averages. However, it is possible to predict the control parameters and apparatus state parameters in real time by using the plasma reflection parameters obtained in real time when processing one wafer. Further, the parallel plate type plasma processing apparatus having a magnetic field is used in the preferred embodiment, but this invention is not limited thereto. The present invention may be applied to various apparatuses having the plasma reflection parameters, the control parameters and/or the apparatus state parameters.

While the invention has been shown and described with respect to the preferred embodiment with reference to the accompanying drawings, but the present invention is not limited thereto. The present invention will be understood by those skilled in the art that various changes and modifications may be made without departing from the spirit and scope of the invention as defined in the following claims.

What is claimed is:

1. A plasma processing apparatus comprising:
a detection unit to detect a plasma reflection parameter representing a plasma state while processing an object to be processed by using a high frequency electric power;
a setting unit to set a plurality of control parameters to control the plasma state;
a storage unit to store a model equation that predicts at least the control parameters and a number of apparatus state parameters based on the plasma reflection parameter; and
a prediction unit for applying to the model equation the plasma reflection parameter obtained when processing an object to be processed to predict at least control parameters and apparatus state parameters during processing.

2. The plasma processing apparatus of claim 1, further comprising:
an observation unit to monitor at least control parameters and apparatus state parameters; and
a comparison unit to compare at least the control parameters and the apparatus state parameters predicted by the prediction unit with at least the control parameters and the apparatus state parameters monitored by the observation unit.

3. The plasma processing apparatus of claim 2, wherein means for signaling an abnormality is connected to the comparison unit.

4. The plasma processing apparatus of claim 1, further comprising a multivariate analysis unit to obtain the model equation.

5. The plasma processing apparatus of claim 4, wherein the multivariate analysis unit includes a unit that operates with a partial least squares method.

6. The plasma processing apparatus of claim 1, wherein the plasma reflection parameter is at least electrical data and optical data based on a plasma generated by the high frequency electric power.

7. A method for monitoring a plasma processing apparatus, which comprises a detection unit to detect a plasma reflection parameter representing a plasma state while processing an object to be processed by using a high frequency electric power; a setting unit to set a plurality of control parameters to control the plasma state; a storage unit to store a model equation that predicts at least the control parameters and a number of apparatus state parameters based on the plasma reflection parameter; and
a prediction unit for applying to the model equation the plasma reflection parameter obtained when processing an object to be processed to predict at least control parameters and apparatus state parameters during processing, the method comprising the steps of:
detecting the plasma reflection parameter representing the plasma state while processing the object to be processed by using the high frequency electric power; and
predicting at least control parameters and apparatus state parameters during processing by applying to the model equation the plasma reflection parameter.

8. The method of claim 7, wherein the plasma processing apparatus comprises an observation unit to monitor at least the control parameters and the apparatus state parameters, and
the method further comprising the steps of:
monitoring at least the control parameters and apparatus state parameters; and
comparing at least the predicted control parameters and the predicted apparatus state parameters with at least the monitored control parameters and the monitored apparatus state parameters.

9. The method of claim 8, further comprising the step of signaling an abnormality based on a result of the comparing step.

10. The method of claim 7, wherein the model equation is obtained by using a multivariate analysis.

11. The method of claim 10, wherein the model equation is obtained by using a partial least squares method.

12. The method of claim 7, wherein the plasma reflection parameter is at least electrical data and optical data based on a plasma generated by the high frequency electric power.

13. A plasma processing method for processing an object to be processed by employing a plasma processing apparatus, which comprises a detection unit to detect a plasma reflection parameter representing a plasma state while processing an object to be processed by using a high frequency electric power; a setting unit to set a plurality of control parameters to control the plasma state; a storage unit to store a model equation that predicts at least the control parameters and a number of apparatus state parameters based on the plasma reflection parameter; and a prediction unit for applying to the model equation the plasma reflection parameter obtained when processing an object to be processed to predict at least control parameters and apparatus state parameters during processing, the method comprising the steps of:
detecting the plasma reflection parameter representing the plasma state while processing the object to be processed by using the high frequency electric power; and
predicting at least control parameters and apparatus state parameters during processing by applying to the model equation the plasma reflection parameter.

14. The method of claim 13, wherein the plasma processing apparatus comprises an observation unit to monitor at least the control parameters and the apparatus state parameters, and
the method further comprising the steps of:
monitoring at least the control parameters and apparatus state parameters; and
comparing at least the predicted control parameters and the predicted apparatus state parameters with at least the monitored control parameters and the monitored apparatus state parameters.

15. The method of claim 14, further comprising the step of signaling an abnormality based on a result of the comparing step.

16. The method of claim 13, wherein the model equation is obtained by using a multivariate analysis.

17. The method of claim 16, wherein the model equation is obtained by using a partial least squares method.

18. The method of claim 13, wherein the plasma reflection parameter is at least electrical data and optical data based on a plasma generated by the high frequency electric power.
